(19) United States
(12) Patent Application Publication
(10) Pub. No.: US 2011/0209742 A1
(43) Pub. Date: Sep. 1, 2011

(54) Method and Structure for a Cool Roof by Using a Plenum Structure

(75) Inventor: Ramachandran Narayanamurthy, El Cerrito, CA (US)

(73) Assignee: PVT Solar, Inc., Berkeley, CA (US)

(21) Appl. No.: 12/896,752

(22) Filed: Oct. 1, 2010

Related U.S. Application Data
(63) Continuation-in-part of application No. 12/794,352, filed on Jun. 4, 2010, now abandoned.
(60) Provisional application No. 61/185,990, filed on Jun. 10, 2009.

(51) Int. Cl. H01L 31/052; F24F 7/02

(52) U.S. Cl. 136/246; 165/47

(57) ABSTRACT

A plenum structure for cooling both a roof and a solar module includes an upper surface comprising at least a portion of a bottom face of a solar module having a length and a width and an under surface comprising a top face of a pan structure disposed a first vertical spacing directly below the upper surface and a second vertical spacing above the roof. The plenum structure includes a first side face and a second side face respectively coupled to the upper surface and the under surface, a first end face and a second end face respectively coupled to upper surface, the under surface, the first side face, and the second side face to enclose a spatial volume defined by the length, the width, and the first vertical spacing.

### CROSS-REFERENCE TO RELATED APPLICATION

This application is a continuation in part application of U.S. patent application Ser. No. 12/794,352, filed Jun. 4, 2010, entitled “A METHOD AND STRUCTURE FOR A COOL ROOF BY USING A PLENUM STRUCTURE” by inventor Ramachandran Narayanamurthy, commonly assigned and incorporated by reference herein for all purposes.

### BACKGROUND OF THE INVENTION

This invention relates to operation of thermal solar systems, and in particular to a method and structure for cooling a roof by using a plenum structure associated with a thermal solar system. The invention has been applied to a thermal solar module on a building structure, but it will be recognized that the invention has a much broader range of applications.

Over the past centuries, the world population has grown rapidly. Along with the population, demand for resources has also grown. Such resources include raw materials such as wood, iron, and copper, and include energy, such as fossil fuels in the form of coal and oil. Industrial countries world wide project more increases in oil consumption for transportation and heating, especially from developing nations such as China and India. Obviously, our daily lives depend, for the most part, upon oil or other fossil fuels, which are becoming increasingly scarce.

Along with the depletion of our fossil fuel resources, our planet has experienced progressive temperature increases, known as “global warming,” recently emphasized by Al Gore, former Vice President. Global warming is an increase in the average temperature of the Earth's air near its surface, which is projected to continue to increase. Warming is believed to be caused by greenhouse gases, which are derived, in part, from use of fossil fuels. The increase in temperature is expected to cause extreme weather conditions and a drastic size reduction of the polar ice caps, which in turn will lead to higher sea levels and a further increase in the rate of warming. Ultimately, effects may include mass species extinctions, and uncertainties that may be detrimental to humans.

Much, if not all of the useful energy found on the Earth, comes from our sun. Most plant life on the Earth achieves life using photosynthesis processes driven by sun light. Fossil fuels such as oil were also developed from biological materials derived from energy associated with the sun. For most living beings on the Earth, sunlight is essential. Likewise, the sun has been our most important energy source and fuel for modern day solar energy. Solar energy possesses many characteristics that are desirable. Solar energy is renewable, clean, abundant, and often readily available.

As an example, solar panels have been developed to convert sunlight into energy. Solar thermal panels often convert electromagnetic radiation from the sun into thermal energy for heating homes, running certain industrial processes, or driving turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Solar panels have great potential to benefit our nation, security, and human users. They can even diversify our energy requirements and reduce the world's dependence on oil and other potentially detrimental sources of energy.

Although solar panels have been used successful for certain applications, there are still limitations. Solar cells are often costly. Depending upon the geographic region, there may be financial subsidies from governmental entities for purchasing solar panels, which otherwise might not be competitive with the purchase of electricity from public power companies. Additionally, the panels are often composed of silicon bearing wafer materials. Such wafer materials are costly and difficult to manufacture efficiently on a large scale. Availability of solar panels is also somewhat scarce. Solar panels are often difficult to find and purchase from limited sources of photovoltaic silicon bearing materials.

From the above, it is seen that techniques for improving operation of a solar related systems are desired.

### BRIEF SUMMARY OF THE INVENTION

This invention relates to operation of thermal solar systems, and in particular to a method and structure for cooling a roof by using a plenum structure associated with a thermal solar system. The invention has been applied to a thermal solar module on a building structure, but it will be recognized that the invention has a much broader range of applications.

In a specific embodiment, the invention provides a method for providing a cool roof by processing fluid within a vicinity of a roof structure. The method includes providing a roof structure having a surface area. Additionally, the method includes transferring a volume of air with a selected flow rate through a plenum structure disposed underlying one or more solar modules and coupled to the roof structure spatially over a height above a portion of the surface area. The roof structure can be configured in a selected color such as white, silver, yellow, or other colors capable of reflecting electromagnetic radiation in the solar spectrum. Each of the solar modules is coupled to each other. The plenum structure an intake region and an exit region for the volume of air. Moreover, the method includes maintaining a roof temperature profile for the portion of the surface area starting from the intake region to the exit region for a predetermined amount of time using at least the flow rate of the volume of air being transported through the plenum structure. The roof temperature profile comprises a first temperature value substantially equal to an ambient air temperature at the intake region to a second temperature value in the vicinity of the exit region depending on the flow rate and substantially smaller than a temperature of bare roof structure outside the portion of the surface area.

In another embodiment, the present invention provides a system for providing a roof maintained within a predetermined temperature range by processing fluid within a vicinity of a roof structure, The system includes a roof structure having a surface area and a plenum structure configured for transferring a volume of air within a selected flow rate. The plenum structure is disposed underlying one or more solar modules and coupled to the roof structure spatially over a height above a portion of the surface area. Each of the one or more solar modules is coupled to each other. The plenum structure has at least an intake region and an exit region for the volume of air. Additionally, the system includes a roof temperature profile configured within he portion of the surface area starting from the intake region to the exit region for a predetermined amount of time using at least the flow rate of the volume of air being transported through the plenum structure. The roof temperature profile comprises a first temperature value substantially equal to an ambient air temperature at the intake region to a second temperature value in the vicinity of the exit region depending on the flow rate and substantially smaller than a temperature of bare roof structure outside the portion of the surface area.

In an alternative embodiment, the present invention provides a system for providing a roof maintained within a predetermined temperature range by processing fluid within a vicinity of a roof structure. The system includes a plenum structure configured for transferring a volume of air within a selected flow rate. The plenum structure is coupled to a roof structure spatially over a height above a portion of a surface area of the roof structure. The plenum structure has at least an intake region and an exit region for the volume of air. Additionally, the system includes a roof temperature profile configured within the portion of the surface area starting from the intake region to the exit region for a predetermined amount of time using at least the flow rate of the volume of air being transported through the plenum structure. The roof temperature profile is configured by a first temperature value substantially equal to an ambient air temperature at the intake region to a second temperature value in the vicinity of the exit region depending on the flow rate and substantially smaller than a temperature of bare roof structure outside the portion of the surface area.

In yet another alternative embodiment, the present invention provides a method for providing a roof within a predetermined temperature range by processing fluid within a vicinity of a roof structure. The method includes transferring a volume of air with a selected flow rate through a plenum structure coupled to a roof structure spatially over a height above a portion of the surface area of the roof structure. The plenum structure has at least an intake region and an exit region for the volume of air. Additionally, the method includes maintaining a roof temperature profile for the portion of the surface area starting from the intake region to the exit region for a predetermined amount of time using at least the flow rate of the volume of air being transported through the plenum structure. The roof temperature profile comprises a first temperature value substantially equal to an ambient air temperature at the intake region to a second temperature value in the vicinity of the exit region depending on the flow rate and substantially smaller than a temperature of bare roof structure outside the portion of the surface area.

In a specific embodiment, the roof temperature profile within the portion of the surface area comprises an average temperature no greater than about 105 Degrees Fahrenheit on a day with 90 Degrees Fahrenheit ambient air temperature. In another specific embodiment, the second temperature value is a less than 20 Degrees Fahrenheit above the first temperature value. In yet another specific embodiment, the method further includes emitting infrared radiation from the roof structure or plenum structure. In yet still another specific embodiment, the roof structure is white in color.

As used herein, the term “cool roof” should be interpreted by ordinary meaning understood by someone of ordinary skill in the art. As an example, the term cool roof has been defined by the California Energy Commission and other entities. See also, for example, http://en.wikipedia.org/wiki/Cool_roof.
In the world of industrial and commercial buildings, a roofing system that can deliver high solar reflectance (the ability to reflect the visible, infrared and ultraviolet wavelengths of the sun, reducing heat transfer to the building) and high thermal emittance (the ability to release a large percentage of absorbed, or non-reflected solar energy) is a cool roof Most cool roofs are white or other light colors.
In tropical Australia, zinc-galvanized (silvery) sheeting (usually corrugated) reflect heat much better than the “cool” color of white. European fashion trends are now using darker-colored aluminium roofing, to pursue consumer fashions.
Cool roofs enhance roof durability and reduce both building cooling loads and the urban heat island effect.
Also known as albedo, solar reflectance is expressed either as a decimal fraction or a percentage. A value of 0 indicates that the surface absorbs all solar radiation, and a value of 1 represents total reflectivity. Thermal emittance is also expressed either as a decimal fraction between 0 and 1, or a percentage. A newer method of evaluating coolness is the solar reflectance index (SRI), which incorporates both solar reflectance and emittance in a single value. SRI quantifies how hot a surface would get relative to standard black and standard white surfaces. It is defined such that a standard black (reflectance 0.05, emittance 0.90) is 0 and a standard white (reflectance 0.80, emittance 0.90) is 100.
Cool roofs are an effective alternative to bulk attic insulation under roofs in humid tropical and subtropical climates. Bulk insulation can be entirely replaced by roofing systems that both reflect solar radiation and provide emission to the sky. This dual function is crucial, and relies on the performance of cool roof materials in both the visible spectrum (which needs to be reflected) and far infra-red which needs to be emitted.
Cool roof can also be used as a geoengineering technique to tackle global warming based on the principle of solar radiation management, provided that the materials used not only reflect solar energy, but also emit infra-red radiation to cool the planet. This technique can give between 0.01-0.19 W/m2 of globally-averaged negative forcing, depending on whether cities or all settlements are so treated[1]. This is generally small when compared to the 3.7 W/m2 of positive forcing from a doubling of CO2. However, in many cases it can be achieved at little or no cost by simply selecting different materials. Further, it can reduce the need for air conditioning, which causes CO2 emissions which worsen global warming. For this reason alone it is still demonstrably worth pursuing as a geoengineering technique.

In other examples, cool roofs have been rated by Energy Star, which is a joint program of the U.S. Environmental Protection Agency and the U.S. Department of Energy designed to reduce greenhouse gas emissions and help businesses and consumers save money by making energy-efficient product choices. Additionally, Cool Roof Rating Council (CRRC) has also created a rating system for measuring and reporting the solar reflectance and thermal emittance of roofing products. Other entities include, but are not limited to, the Green Globes system, which is used in Canada and the United States. Other examples include LEED, among others. See also, Consumer Energy Center. Of course, there can be other variations, modifications, and alternatives.

In another specific embodiment, the present invention provides a plenum structure for cooling both a roof and a solar module on the roof. The plenum structure includes an upper surface comprising at least a portion of a bottom face of a solar module having a length and a width. The plenum structure further includes an under surface comprising a top face of a pan structure disposed a first vertical spacing directly below the upper surface and a second vertical spacing above the roof. Additionally, the plenum structure includes a first side face and a second side face respectively coupled to the upper surface and the under surface. The plenum structure further includes a first end face and a second end face respectively coupled to upper surface, the under surface, the first side face, and the second side face to enclose a spatial volume defined by the length, the width, and the first vertical spacing. Furthermore, the plenum structure includes one or more opening structures being associated with the first end face for drawing an airflow into the spatial volume and an exit opening being disposed in a vicinity of the under surface and the second end face for extracting out the airflow flowing through the spatial volume. The under surface and the under surface modulate the airflow for removing thermal energy generated by the solar module at least partially.

In yet still another embodiment, a method for providing a cool roof utilizing a plenum structure associated with a solar panel mounted on the roof is provided. The method includes mounting a first rail structure and a second rail structure to a roof. The first rail and the second rail is inclined with a slope with respect to a horizontal plane. The method further includes installing a pan structure to the first rail structure and the second rail structure. The pan structure includes a planar material having a width and a length substantially inclined with the slope to cover a portion of the roof. Additionally, the method includes coupling a solar panel to the first rail structure and the second rail structure. The solar panel is disposed at a distance directly above the pan structure to form a plenum structure characterized by a volume of spatial region caped between the solar panel and the pan structure and sided with the first rain structure and the second rail structure. The plenum structure further includes at least an intake region near a lower end of the pan structure inclined with the slope and an exit region located substantially near a higher end of the pan structure. Furthermore, the method includes drawing an airflow at a flow rate through the plenum structure from the intake region to the exit region. Moreover, the method includes maintaining a temperature profile through the plenum structure using at least the flow rate of the airflow modulated by the pan structure.

The present technique provides an easy to use process that relies upon conventional technologies such as thin film photovoltaic modules, which can be configured as a thermal solar device. Additionally, the present method provides a process that is compatible with the conventional photovoltaic module without substantial modifications to equipment and processes. Preferably, the invention provides for an improved solar module operation procedure, which is less costly and easy to handle, and has both electrical and thermal energy generation and utilization. In a specific embodiment, the present method and system provides for control of photovoltaic and thermal solar operation. In another specific embodiment, the present method and system are applicable for mounting the solar modules on any type of roof sloped or not, utilizing a inclined mounting rail and added pan structure for forming a plenum structure. The added pan structure plus proper attachment of a tedlar to a bottom face of the solar module the airflow in the plenum structure can be further modulated to enhance the thermal energy transfer from the heated solar module to the energy transfer module with much improved efficiency. Depending upon the embodiment, thermal energy in the form of heat can be used to improve efficiency of the thin film photovoltaic cell according to an embodiment of the present invention. In other embodiments, the present invention provides a method and structure having an improved efficiency per area of at least 10 percent and greater or 25 percent and greater using a thin film photovoltaic absorber depending upon the application. In a specific embodiment, the present improved efficiency is for a thin film based photovoltaic material, which traditionally has lower efficiencies. In a preferred embodiment, the overall energy conversion efficiency of the thermal solar system, including both thermal solar module and photovoltaic device using a thin film photovoltaic material, can be greater than about 30 percent. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagram of a thermal solar system disposed on a roof structure according to an embodiment of the present invention.

FIG. 2 is a simplified side view diagram of a plenum structure for cooling roof according to an embodiment of the present invention.

FIG. 2A is a schematic side view diagram of a plenum structure according to an embodiment of the present invention.

FIG. 2B is a simplified perspective view diagram of a plenum structure mounted on a roof of a building structure according to an embodiment of the present invention.

FIG. 3A is a simplified view of a section of dark roof versus a section of white roof in ambient air under the sun.

FIG. 3B is a simplified view of the dark roof and the white roof each with a PV panel installed.

FIG. 3C is a simplified view of the dark roof and the white roof each having a PVT panel with a plenum structure installed according to an embodiment of the present invention.

FIG. 4A shows simplified roof temperature profiles for dark roof with and without PVT plenum structure according to an embodiment of the present invention.

FIG. 4B shows simplified roof temperature profiles for white roof with and without PVT plenum structure according to an embodiment of the present invention.

FIG. 4C shows simplified roof temperature profiles of a cool roof plenum structure respectively with high and low air flow rate according to an embodiment of the present invention.

FIG. 5 is a simplified side view diagram of a plenum structure according to another embodiment of the present invention.

FIG. 6 is a simplified perspective view diagram of a plenum structure associated with a solar panel on a roof of a building structure according to another embodiment of the present invention.

FIG. 7 is an exemplary textured tedlar attachment of a bottom face of a solar panel according to an embodiment of the present invention.

FIG. 8 is an exemplary pan structure with turbulators according to an embodiment of the present invention.

FIG. 9 shows exemplary textures or turbulators associated with tedlar attachment or pan structure of a plenum structure according to one or more embodiments of the present invention.

FIGS. 10A through 10E are exemplary structures of air intake region of a plenum structure according to one or more embodiments of the present invention.

FIG. 11 shows exemplary temperature profiles associated with a plenum structure and cool roof respectively with high/low flow rate and with/without a pan structure according to an embodiment of the present invention.

### DETAILED DESCRIPTION OF THE INVENTION

The present invention relates to operation of thermal solar system. More particularly, the present invention provides a method and structure for cooling roof by using a plenum structure associating a thermal solar system. Merely, by way of example, the present invention has been applied to a thermal solar module configured on a building structure, but it would be recognized that the invention has a much broader range of applications.

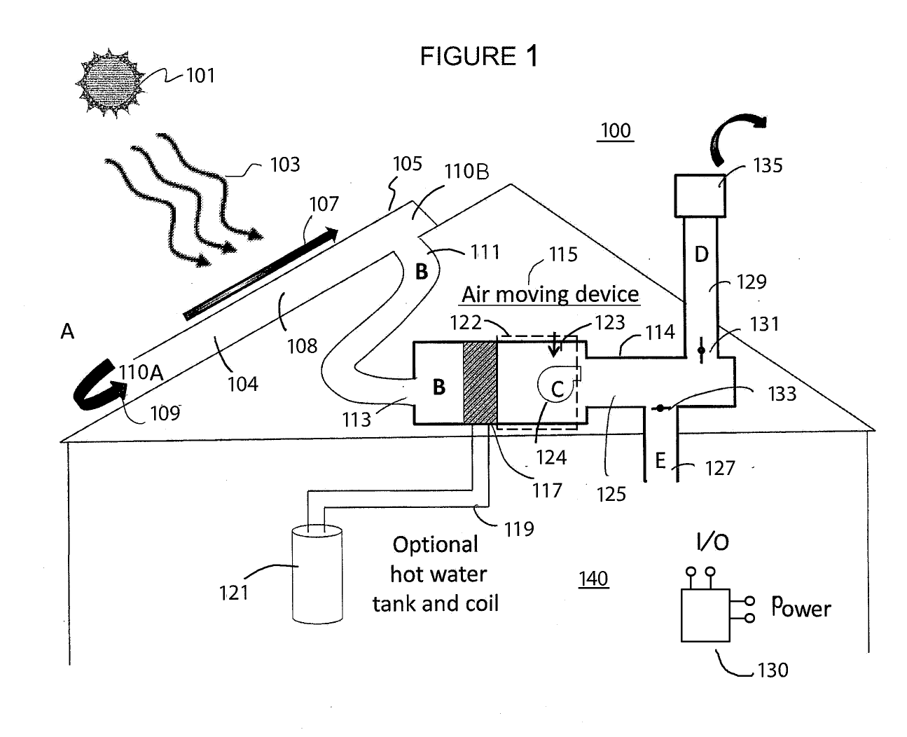

FIG. 1 is a simplified side view diagram of a thermal solar system according to an embodiment of the present invention. This diagram is merely an example, which should not unduly limit the scope of the claims herein. One of ordinary skill in the art would recognize other variations, modifications, and alternatives. As shown, the thermal solar system 100 includes a plurality of thermal modules spatially configured as an N by M array, where N is an integer equal to or greater than 1, and M is an integer greater than 2 spatially disposed and attached to a spatial face of a building structure. The spatial face can be a roof, building side, rack, or the like. In a specific embodiment, the plurality of thermal modules is configured to form an aperture region 105 and a backside region 104. In one or more embodiments, the thermal solar modules can be combined with photovoltaic modules or solely thermal modules or photovoltaic modules configured for thermal use to provide a heat source.

In a specific embodiment, electromagnetic radiation 103 from the sun or other radiation source illuminates on the aperture region 105. In one or more embodiments, thermal energy is transferred through the plurality of thermal modules so that the thermal energy is applied to a working fluid 109 such as air, which traverses 107 is an upward direction through a plenum structure 108 configured from at least the backside region 104. In a specific embodiment, the plenum structure 108 has one or more intake regions 110A and one or more exhaust regions 110B. The plenum structure 108 is a substantially closed physical enclosure of a volume including the one ore intake regions 110A and the one or more exhaust regions 110B. For example, the one or more intake regions 110A can be configured near a lower portion of the plurality of thermal modules to draw colder working fluid 109 (for example air from outside), although there can be other spatial locations. Additionally, the one or more exhaust regions 110B can be a single exhaust region or multiple exhaust regions disposed spatially in a configuration near an upper portion of the plurality of thermal modules.

Referring again to FIG. 1, the thermal solar system has a first duct 111 coupled to the one ore more exhaust regions 110B. In a specific embodiment, the first duct 111 can couple into a thermal transfer module 115 having a fluid flow intake region 113 coupled to the first duct 111, a fluid flow exit region 125 coupled via a second duct 114, and a fluid drive region 123 spatially disposed between the fluid flow intake region 113 and the fluid flow exit region 125. As used herein, the terms “fluid exit region”, “fluid flow intake region”, “fluid drive region” and others are not intended to be limiting and should be interpreted by ordinary meaning Also shown are valves or dampers 131, 133 which respectively connect to one or more air pathways 129, 133 to an outside region via exhaust 135 or back into the building structure via exhaust 127.

In a specific embodiment, the thermal transfer module 115 has an air moving device 122 comprising a drive device 124 coupled to a blower device (not being detailed explicitly). In a preferred embodiment, the drive device 124 is spatially disposed within the fluid drive region 123. In a specific embodiment, the drive device 124 comprises an electric motor with high temperature windings which can withstand about 165 Degrees F. As merely an example, the electric motor is a Class F and greater under the trade association for the Association of Electrical and Medical Imaging Equipment Manufacturers, commonly called “NEMA”. In a specific embodiment, the drive device is operable at a range from about 400 RPM to 4000 RPM, but can be others. In a preferred embodiment, the blower device comprises a fan device having a centrifugal configuration operably coupled to the drive device. Such blower device comprises one or more turbulation elements. In a specific embodiment, the turbulent elements include a plurality of blades, which are configured to move high volumes of fluid and in particular air with a controlled flow rate from the plenum structure 108 through the first duct 110 and subsequently the fluid drive region 123, fluid exit region 125, to one or more exhaust regions 127 and 135. In a preferred embodiment, the fluid flow comprises air flow having temperatures ranging from about 32 Degrees Fahrenheit to about 200 Degrees Fahrenheit or less based upon the temperature insulation rating of the drive device 124.

In a specific embodiment, the thermal solar system has a controller device 130 coupled to the air moving device 122 for controlling the fluid flow. The controller device 130 couples one or more sensing devices operably coupled to the drive device. In an embodiment, the one or more sensing devices are disposed spatially within a vicinity of the drive device 124. In an implementation, the one or more sensing devices are temperature sensors each comprising a thermocouple or other type of sensing device capable of receiving information that is indicative of temperature (at least taking an analog or a digital signal relative to a specific temperature value) of the drive device 124. As an example, the sensing device can be a snap action bi-metal or the like or others.

The thermal solar system 100 is configured to improve the mean time between failures of the drive device 124. As used herein, the term “failure” generally refers to a chronic or catastrophic failure of the drive device, but can have other meanings consistent with ordinary meaning In a specific embodiment, the drive device is characterized by a life cycle Mean Time Between Chronic Failure MTBF of greater than 20,000 hours for a class of insulation for the drive device. In a specific embodiment, the drive device 124 is characterized by an MTBF of about 10,000 hours and less when the temperature within the fluid drive region 123 exceeds 200 Degrees Fahrenheit.

In a specific embodiment, the controller device 130 includes input/output for power, input/output for one or more sensing devices, and input/output for signal control and/or signal feedback. As an example, the controller device 130 can be a computer system, including microprocessor device, memory device, and input/output drivers and the like. As another example, such controller can be one developed by PVT Solar or other suitable companies such as Siemens Programmable Logic Controller, or others.

In an implementation, the controller device 130 is configured to operate the blower device in a first direction to cause fluid flow from at least the fluid flow intake region 113 to the fluid flow exit region 125 and to maintain a fluid (air) temperature of no greater than 200 Degrees Fahrenheit within the fluid drive region 123. In a specific embodiment, the air moving device 122 and preferably the drive device is maintained below about 200 Degrees Fahrenheit or more preferably below 145 Degrees Fahrenheit or more preferably below 125 Degrees Fahrenheit, or alternatively, less than 15 Degrees Fahrenheit above an ambient air temperature for a particular day, but can be others. The controller device 130 is also configured to send one or more signals to at least change the first direction of fluid flow by controlling the blower device to a second direction to cause fluid flow from a third region to the fluid drive region 123 to initiate removal of thermal energy from the fluid drive region 123. In a specific embodiment, the third region can be from an interior region 140 of the building structure through the exhaust 127 and/or ambient (outer) region of the building structure through exhaust 135. In a preferred embodiment, cool air from the third region traverses back across the drive device 124 to remove thermal energy therefrom to prevent heat-damage to the drive device.

In another specific embodiment, the controller device 130 is also configured to maintain the volume of air within the plenum structure 108 substantially free from a no flow condition for a time period of greater than ½ hours while the fluid flow is changing from the first direction to the second direction mentioned above. In a specific embodiment, the no flow condition occurs for less than one minute. In one or more embodiments, the thermal solar system 100 substantially prevents the no flow condition to maintain the plurality of thermal solar modules free from heat-damage and/or detrimental reliability issues. In a specific embodiment, the no flow condition occurs when the hot air through the plenum structure 108 is substantially free from any air velocity or such air velocity is less than about 2 feet per minute or others.

Referring again to FIG. 1, the second duct 114 is coupled to the fluid exit region 125. In a specific embodiment, the second duct 114 is coupled to the third region mentioned above, which has a temperature of less than 200 Degrees Fahrenheit or less than about 125 Degrees Fahrenheit or less than about 100 Degrees Fahrenheit, but can be others. As shown, the thermal solar system can also include a heat exchanger 117 spatially disposed between one or more regions coupled to the air moving device 122 to capture thermal energy in an efficient manner. The heat exchanger 117 also is configured to reduce the temperature of fluid flow before it traverses over the drive device 124 according to a specific embodiment. As shown, the heat exchanger 117 couples to piping 119, which connects to a water tank 121 for preheating water therein. The water tank 121 can be a conventional water heater modified to include the suitable piping 119 to couple with the heat exchanger 117 to utilize the thermal energy from the thermal solar system for heating the water instead of using traditional gas burner or electrical burner. Of course, other heating or heat storage apparatus can be utilized for the same purpose.

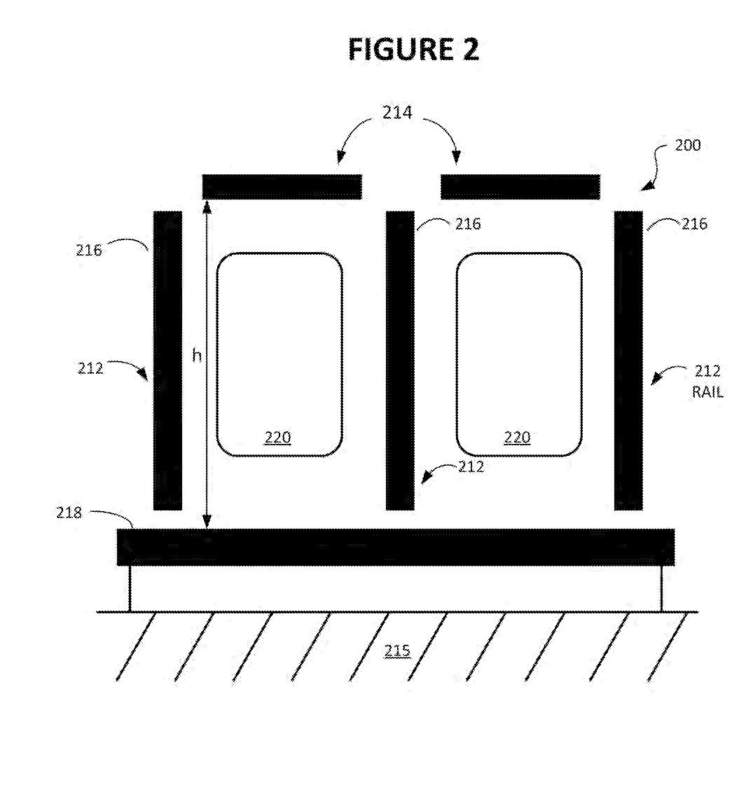

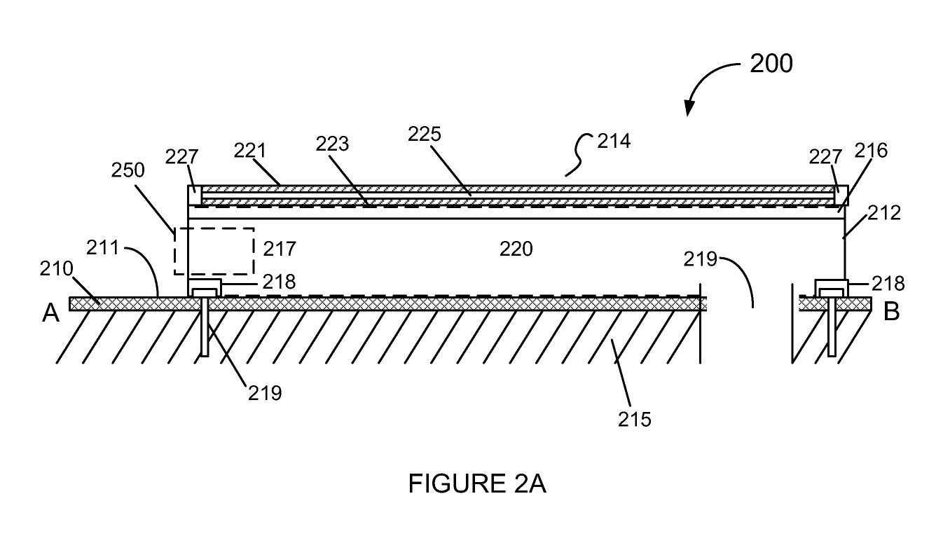

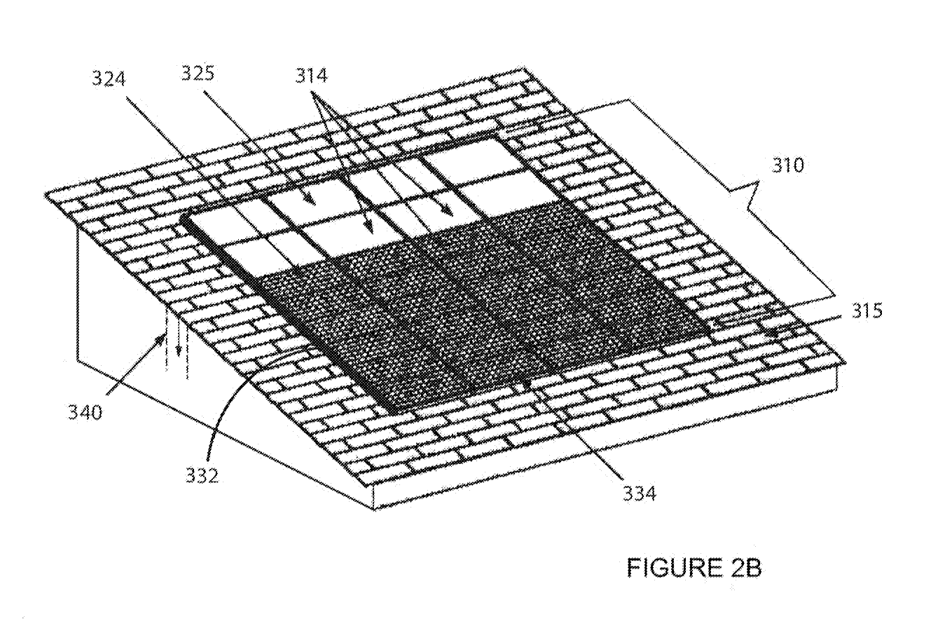

FIG. 2 is a simplified side view diagram of a plenum structure for cooling roof according to an embodiment of the present invention. This diagram is merely an example, which should not unduly limit the scope of the claims herein. One of ordinary skill in the art would recognize other variations, modifications, and alternatives. As shown, the plenum structure 200 is configured to couple/support one or more solar modules 214, under one or more embodiments of the invention. In a specific embodiment, the plenum structure 200 includes an upper region composed of at least a portion of the one or more solar modules 214, which can be interlinked together, a lower region composed of partially the surface area 211 of the roof structure 210, and a rack assembly disposed along the side of the plenum structure, substantially enclosing a volume of space 220. As shown, the rack assembly includes a plurality of rail structures 212 that provide support for each of the one or more solar modules 214. When installed, the rail structures 212 support the individual solar modules 214 a given height h above the surface of the roof structure 210 which has an underlying body 215. The underlying body 215 may correspond to any platform or structure on which the solar modules 214 are mounted. For example, underlying body 215 may correspond to a roof of a commercial or residential building or other suitable structure. The solar modules 214 may correspond to photovoltaic solar cells that convert solar energy into electricity, or alternatively, solar heating or thermal modules which directly generate heat using solar energy. In an example, the solar modules 214 can be simply an insulated glass assembly consisting of two high reflectance glass panels with a low thermal conductivity material between the panels. Alternatively, the solar modules can be a combination of photovoltaic solar cells and thermal modules according to one or more embodiments.

According to one or more embodiments, the rail structures 212 are adjustable pair-wise, or in other combinations, in order to hold in place solar modules 214 of various dimensions and sizes. In one or more embodiments, the solar modules 214 are supported by a combination of retention structures 216. Each retention structure 216 may be provided with a corresponding one of the rail structures 212. In one or more embodiments, each retention structure 216 is a structural feature of the corresponding rail structure 212. For example, each rail structure 212 may comprise of multiple interconnected segments, and the retention structure(s) may be one of the interconnected elements. Alternatively, the retention structures 216 may be integrated or unitarily formed with the individual rail structures 212. Each retention structure 216 supports individual solar modules 214 by grasping edge segments. In one or more embodiments, the retention structures 216 and/or rail structures 212 are adjustable to grasp and support solar modules 214 of varying thicknesses and forms.

Referring again to FIG. 2, an embodiment provides that rail structures 212 are mounted indirectly to the roof 210 through use of a set of strut runners 218. Each strut runner 218 mounts to the roof 210 and to multiple rail structures 212, thus providing lateral support to maintaining the rail structures 212 upright, while at the same time providing a buffer between the individual rail structures 212 and the underlying body 215. The rail structures 212 may mount to the strut runners 218, and the strut runners may mount to the roof 210. The side view of FIG. 2 shows a cross section the structures along horizontal direction being parallel to the strut runners 218. The rail structures 212 are along the sloped (if any) direction and so do lengths of the channels 220.

According to an embodiment, combination of at least a portion of the one or more solar modules 214, a partial surface area of the roof structure 215, and the rail structures 212 provides some basic elements for forming a plenum structure 200. Additionally, the plenum structure 200 becomes part of a solar heat exchange system that uses heat generated from the solar modules 214 for any one of various useful purposes. The heat exchange may be enabled by the formation of one or more channels 220 between an underside of solar modules 214 and an upside of the underlying body 215. An individual channel 220 may be defined or enclosed in part by one or more of the rail structures 212, as well as partial surface areas of the underlying body and partial underside surface areas of the solar modules 214. The individual channel 220 may occupy at least a portion of the thickness defined by the height h. The plenum structure 200 further includes an opening region 217 for drawing cooler air into the channel 220 and an exhaust 219 for directing hotter air out of the channel for achieving the roof cooling. More features of the plenum structure can be found via schematic illustrations of FIGS. 2A and 2B below.

FIG. 2A is a schematic side view diagram of a plenum structure according to an embodiment of the present invention. This diagram is merely an example, which should not unduly limit the scope of the claims herein. One of ordinary skill in the art would recognize other variations, modifications, and alternatives. As shown, the plenum structure 200 includes a simple thermal module 214 made of an insulation glass assembly mounted on a surface region 211 of a roof 210. In a specific embodiment, the insulation glass assembly includes two high reflectance glass panels 221 and 223 with a low thermal conductivity material 225 between the panels. The glass panel 221 or 223 can be a regular window glass but with tempered treatment to enhance its strength to resist impact of foreign object such as hail. The low thermal conductivity material 225 can be nitrogen, or argon, or other inert gas or the likes. In an alternative embodiment, the thermal module 214 represents a fully assembled photovoltaic solar module which has an upper window glass 221 and a bottom glass substrate 223 and one or more solar cells formed in between. The solar cells can be poly-silicon based solar cells, or thin film absorber based solar cells, or any combinations of both types. The glass assembly is sealed or laminated surrounding edges of both panels by a structural element 227 and mounted through one or more retention structures or interconnected elements 216 to a rail structure 212. As shown, the rail structure 212 is along the sloped (if any) direction of the roof 210. For example, the label A indicates a relative lower region of the roof and B a relative upper region of the roof. The rail structure is mounted to the roof 210 through a strut runner 218 into the underlying body 215 by a pin element 219. The strut runner 218 is then in parallel to horizontal direction (into the view plane of FIG. 2A). An opening 217 is located at the lower end of the plenum structure for drawing cooler air from ambient. Optionally, an air director device 250 can be added there for enhancing fluid flow when necessary. Another opening 219 is located on upper region of the roof surface, which is designed for air exhaust for directing hot air (or fluid) out of the partial enclosed volume 220 of the plenum structure 200. In an embodiment, the opening 219 is coupled to a duct structure (not fully shown) which leads the hot air to a heat exchange/transfer module associated with the plenum structure.

In one or more embodiments, the plenum structure 200 is associated with the thermal solar system 100 of FIG. 1 which may further include other components, such as a plurality of thermal panels, as well as air directors that draw air into the channels 220, and/or push the air through the channels. When installed as part of a thermal solar system, the plenum structure 200 may be positioned to supply heated air to such air directors, and to be proximate to the environment that is to receive or use the heated air. For example, the plenum structure 200 may be installed on the rooftop of a dwelling, and also direct heated air into a vent or air circulation system of the dwelling as part of its ability to heat air in the enclosed volume or channel 220. Useful purposes for generating heat from the solar modules 214 may include, for example, any one or more of the following: (i) cooling the individual solar modules 214 (when they are photovoltaic cells) so as to make them more efficient, (ii) pulling air from the environment underneath the solar modules 214 for purpose of heating the air for another closed environment or system (e.g. for a house), and (iii) circulating air from the closed environment or system underneath the solar modules 214 to heat that air and use it for heat.

FIG. 2B is a simplified perspective view diagram of a plenum structure associated with a thermal solar system according to an embodiment of the present invention. This diagram is merely an example, which should not unduly limit the scope of the claims herein. One of ordinary skill in the art would recognize other variations, modifications, and alternatives. As shown, the plenum structure 310, which is installed in association with a set of solar modules 314 covering at least a portion of surface area of an underlying body 315. The plenum structure 310 may be structured and adapted to include rack assembly features of plenum structure 200 described earlier with one or more embodiments of the invention. The underlying body 315 may correspond to, for example, a rooftop or roof structure of a building or dwelling. In general, the underlying body 315 may correspond to any area, surface or platform that can receive sunlight and be connected to a building, place or location that can use the solar energy.

Embodiments of the invention contemplate that different types of solar modules 314 may be employed in various implementations and context. For example, as shown by the simplified diagram of FIG. 2B, the solar modules 314 include photovoltaic modules 324 and thermal modules 325. The photovoltaic modules 324 can be made from cells based on pure/poly silicon pn junctions or thin-film semiconductor pn junction. The thermal modules 325 can be made specifically to absorb heat from sunlight. An example of the thermal module can be an insulated glass assembly comprising a double glass panels with a non-conductive material sealed in-between. Under one or more embodiments, the perimeter may include one or more sealed lengths 332 on two sides and upper edge and an open length 334 located at the lower edge. The open length 334 is substantially the same as the opening 217 in FIG. 2A, from which air from the environment is drawn into the channels. The channels or the volume enclosed by the solar modules and a portion of surface area of the underlying body and between a pair of rail structures of the rack assembly that are provided for purpose of constraining airflow. Air drivers and directors (not show) may drive (e.g. push or pull) air within the formed channels or re-direct to other regions through one or more ducts or pathways. The solar modules 314 generate heat, either through design or as an inherent by-product. According to one or more embodiments, this heat warms the air as it is drawn from the environment and pulled through the channels formed underneath the solar modules 314.

Numerous alternatives and variations are contemplated. For example, all of the perimeter of the plenum structure 310 may be sealed, and air may be drawn from interior of a dwelling or building structure beneath the underlying body 315 on which the rack assembly of the plenum structure 310 is provided. Then air may be pushed through channels, then back into the dwelling when warmed. Alternatively, some or all of the open length 334 may be sealed, or conversely, portions of the sealed lengths 132 may be opened or perforated as part of a channel. As shown, FIG. 2B illustrates an implementation in which heated air is directed into a duct 340 within a structure beneath the underlying body 315. For example, warm air may heat a dwelling on which the rack assembly of the plenum structure 310 is installed, and the duct 340 enables the heated air to flow into a circulation system of the dwelling. As mentioned, the solar modules 314 associated with the plenum structure 310 may be formed by a combination of the photovoltaic modules 324 and the thermal modules 325. The photovoltaic modules 324 can generate some residual heat when receiving solar energy and converting the solar energy into electrical current. In contrast, the thermal modules 325 may directly convert the solar energy into heat at a higher efficiency. The use and number of thermal modules 325 may depend on the use of the heated airflow, as well as the environment where the plenum structure 310 is installed. For example, when the purpose of heating air in the channels is to supply warm air to a dwelling of the underlying body 315, the thermal modules 325 have more use in colder environments, while warm environments may require only use of photovoltaic modules 324. Even in cold environments, thermal modules 325 may be used to convert solar energy into hot air due to the high operating efficiency achieved by their designs, and additional components may be used to drive the hot air into the dwelling.

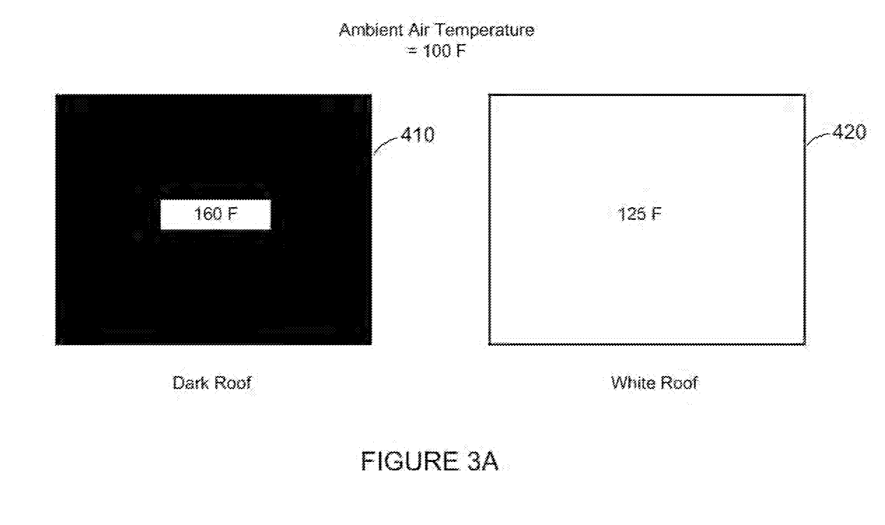

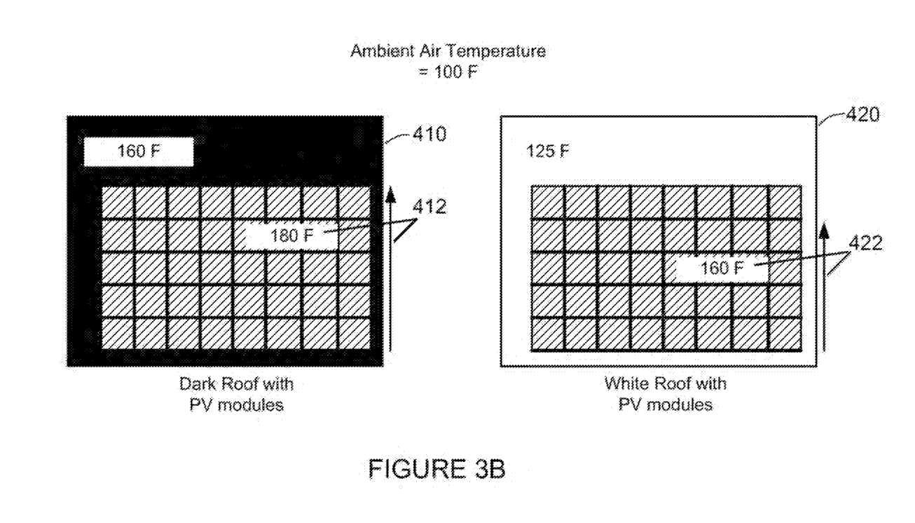

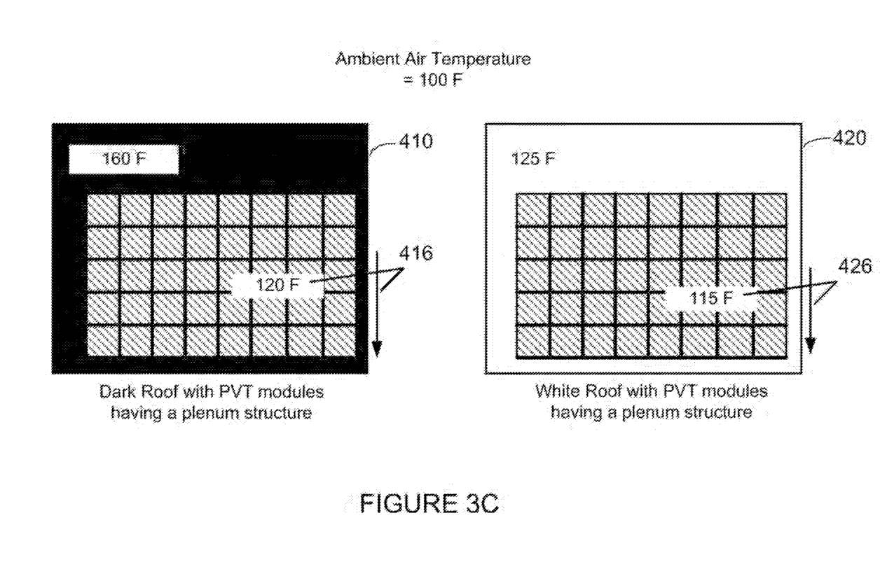

One or more embodiments of the present invention with and the roof cooling advantages using a plenum structure over conventional roof with or without a solar energy system installed can be further illustrated by several examples shown below. FIG. 3A is a simplified view of a section of dark roof versus a section of white roof in ambient air under the sun. A dark roof refers to a roof with a surface region 410 that substantially absorbs the incident sun light and transfer to heat. In a sunny day with ambient air temperature of about 100 Degrees Fahrenheit, the surface temperature of the dark roof can be reached to about 160 Degree Fahrenheit or greater. If the roof is treated to become a cooled white roof with some portion of incident light being reflected, then the surface region 420 of the white roof can have its surface temperature lowered to about 125 Degrees Fahrenheit under the same ambient condition.

Assuming that a solar energy system, for example a conventional PV system including a N×M matrix of modules, is installed respectively on these roofs, as shown in FIG. 3B. The PV system does its work to convert sun light (at least partially) to electric power, while it also generates a substantial amount of heat. Part of the heat is absorbed by each PV module itself and at least a portion of the heat is released to the air below the PV system which drives the surface temperature of the roof (the spatial region covered by the PV system) much higher. Arrow 412 is used to indicate the roof temperature increase caused by the PV system installed over a surface region on the dark roof 410. This is also true for the case with white roof 420, where arrow 422 is referred to corresponding temperature increase of the roof surface region covered by the PV system installed thereon. However, the conventional PV system neither utilizes such the portion of the heat, nor prevents such heat from inducing some bad side effects to both the PV system itself and the dwellings on which the PV system is installed. After replacing the conventional PV system with a PVT system having a plenum structure (underneath the PVT panel), the roof temperature can decrease, instead of increase, to form a cool roof. In addition, the portion of heat can be effectively utilized or stored for many other applications. As shown in FIG. 3C, the dark roof and the white roof each has a PVT system with a plenum structure installed according to an embodiment of the present invention. Arrow 416 represents a lowered roof temperature (compared to bare dark roof surface) with the PVT system having the plenum structure installed. Similarly, arrow 426 also represents a lowered roof temperature (compared to bare white roof surface) with a PVT system having the plenum structure installed. More details of the roof temperature profiles associated with the plenum structure using air flow control can be found below and throughout the specification.

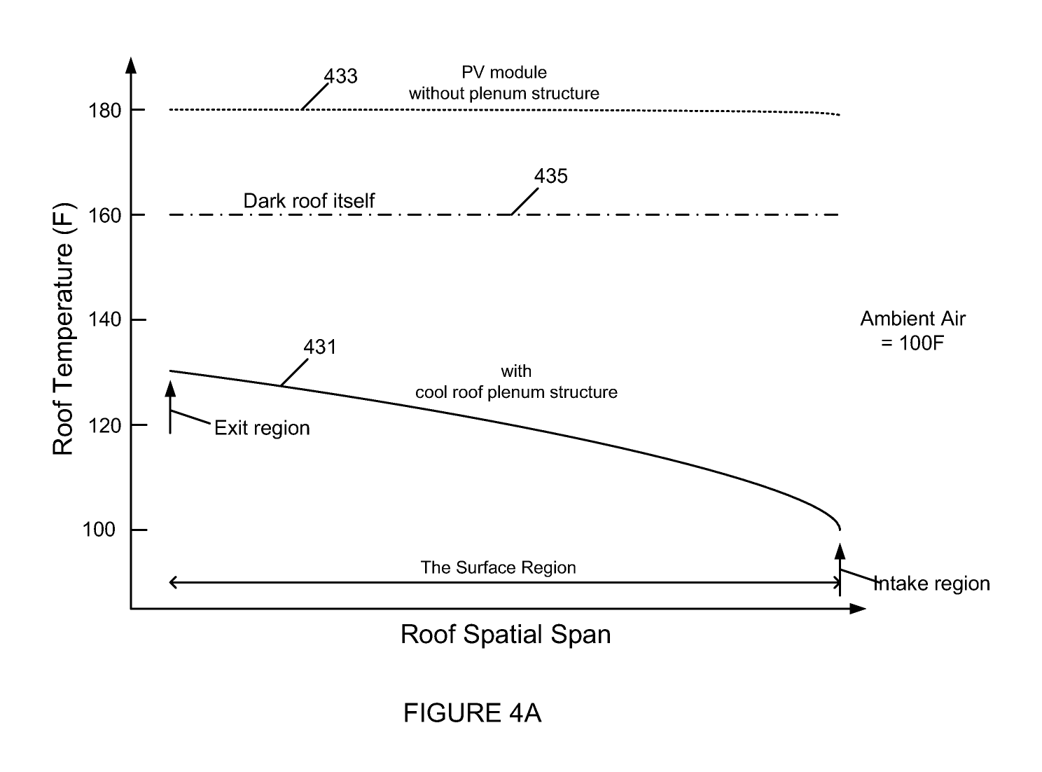

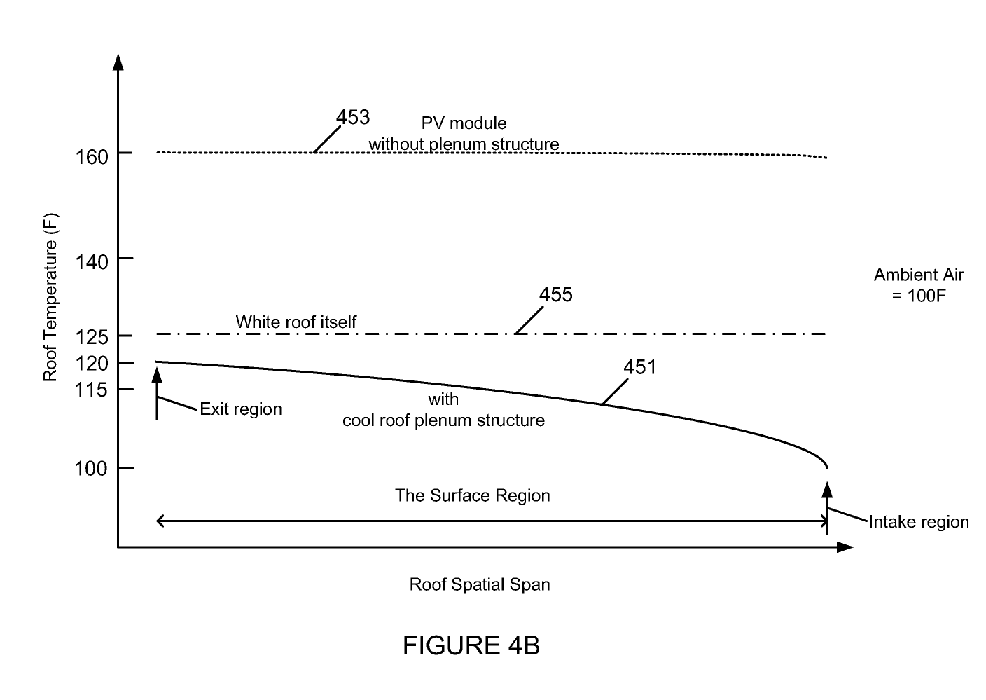

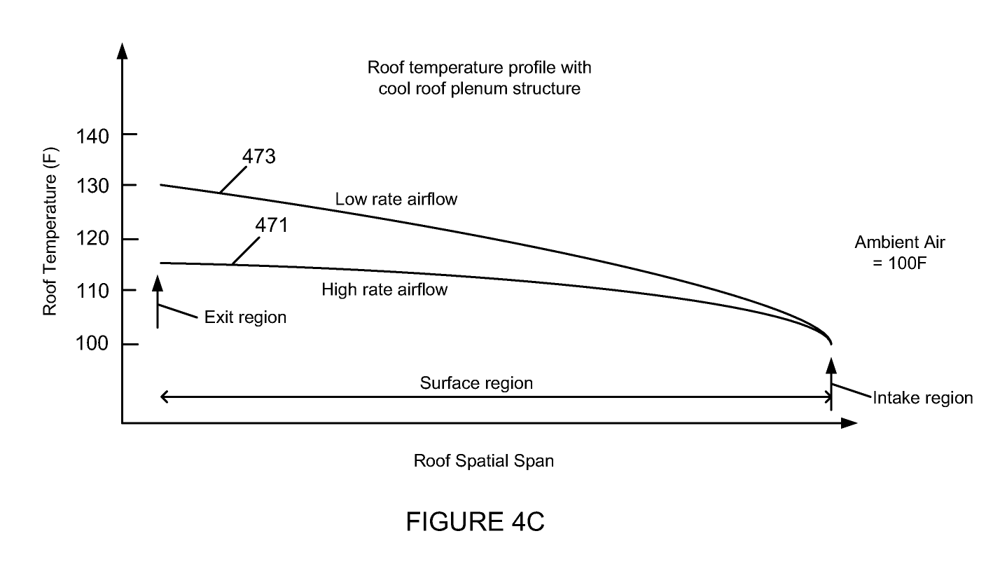

FIG. 4A shows simplified roof temperature profiles for dark roof with and without a plenum structure according to an embodiment of the present invention. This diagram is merely an example, which should not unduly limit the scope of the claims herein. One of ordinary skill in the art would recognize other variations, modifications, and alternatives. As shown, a dark roof (for example, dark roof 410 in FIG. 3A) is exposed under the sun with an ambient air temperature of about 100 Degrees Fahrenheit. By itself, the roof temperature can reach to about 160 Degrees Fahrenheit, as indicated by curve 435.

If the roof has a conventional PV module installed on a portion of surface area, without a plenum structure to transfer the heat generated by the PV module, the roof temperature can be increased quickly across the spatial area. In a specific embodiment, even though the PV module covers the surface so that at least near an intake region the roof temperature may be lowered (compared to bare roof under the sun), most portions of the surface area have higher temperature compared to bare roof, because of a substantial amount of heat is generated from the PV module that heat the air between the PV module and the roof surface. Curve 433 provides an example of the temperature profile for this case, which shows a maximum temperature can be as high as 180 Degrees Fahrenheit.

In another embodiment, if a plenum structure is added to the conventional PV module, the temperature profile is represented by curve 431 across the same spatial surface area from an air intake region (of the plenum structure) to an air exit region of the plenum structure. In a specific embodiment, the plenum structure can be the same as plenum structure 310 shown in FIG. 2B, with intake region 324 and exit region 340. As shown in FIG. 4A, the roof temperature is actually reduced compared to a bare roof under the sun, due to the plenum structure using at least a flow rate of the air between the PV module and roof surface. On average, the roof temperature is only about 120 Degrees Fahrenheit (maximum at about 130 Degrees Fahrenheit). Of course, there are many variations, alternatives, and modifications in PV module, roof structure, installation details, and air flow rate variations. One of ordinary skilled in the art should recognize that the above illustration does not unduly limit the scope of the claims herein. For example, a PVT system may include both PV solar module and thermal solar module, and each type alone, or any other combinations. The corresponding temperature profile may have different slope or curvature or maximum point depending on the length of the module, the plenum structure layout, the air flow rate, etc. In a specific embodiment, the maximum roof temperature in the plenum structure can be maintained about 20 Degrees Fahrenheit or less above ambient air temperature, which is well below (or being cooled from) possible roof temperature of a bare roof surface under the sun.

FIG. 4B shows simplified roof temperature profiles for white roof with and without a plenum structure according to an embodiment of the present invention. This diagram is merely an example, which should not unduly limit the scope of the claims herein. One of ordinary skill in the art would recognize other variations, modifications, and alternatives. As shown, a cool white roof (for example, white roof 420 in FIG. 3A) is exposed under the sun with an ambient air temperature of about 100 Degrees Fahrenheit. By itself, the roof temperature can reach to about 125 Degrees Fahrenheit, as indicated by curve 455. Curve 453 represents the white roof having a conventional PV module installed without the plenum structure. Apparently, the roof temperature is much greater than the bare roof on most portion of the roof surface area covered by the PV module. Curve 451 represents the same white roof having a plenum structure installed to drive air flow between the PV module panel and roof surface. As the result, the whole roof temperature becomes lower than the bare roof, achieving a cool roof function according to one or more embodiments of the present invention. In an example, at ambient air temperature of about 100° F., the white roof can be heated to about 125° F., while a (portion of) cool roof using plenum structure according to an embodiment of the present invention can be only 120° F. at most or only about 115° F. on average across the whole covered surface area. In an embodiment, the maximum roof temperature within the plenum structure can be maintained about 20 Degrees Fahrenheit or less above ambient air temperature, which is well below (or being cooled from) possible roof temperature of a bare roof surface under the sun.

FIG. 4C shows simplified roof temperature profiles of a cool roof plenum structure respectively with high and low air flow rate according to an embodiment of the present invention. This diagram is merely an example, which should not unduly limit the scope of the claims herein. One of ordinary skill in the art would recognize other variations, modifications, and alternatives. As shown, a curve 471 represents a roof temperature profile across the spatial region of the surface area covered by a cool roof plenum structure driving the air in a relative high flow rate from an intake region of the plenum structure to an exit region. This temperature profile is compared with another curve 473 representing a roof temperature profile of the same system with a relative low air flow rate. In an embodiment, the cool roof plenum structure can use at least the air flow rate to control the roof temperature to a desired result for a specific roof structure on which the cool roof plenum structure is installed. Of course, there can be other variations, modifications, and alternatives. For example, the flow rate of the volume of air in the plenum structure being transferred for maintaining the roof temperature profiles can range from zero to about 200 cubic feet per minute and greater. Depending on the application, an optimum flow rate can always be selected for a specific plenum structure installment, aiming for achieving greatest possible reduction of in roof cooling energy with a lowest usage in power for driving the air flow. Therefore, an optimal operation of a cool roof plenum structure can be performed in a well-controlled manner, providing highest possible overall energy conversion efficiency of more than 30%. Here the term “high” or “low” flow rates merely refers to its actual meaning when both are compared together and do not intend to define a particular range as high or low.

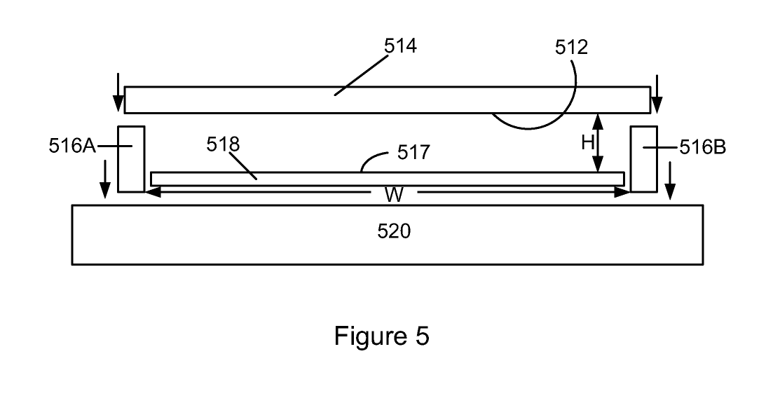

FIG. 5 is a simplified side view diagram of a plenum structure according to another embodiment of the present invention. As shown, a pair of mounting rails 516A and 516B are attaching to a top of a roof structure 520, separated by a width W. A pan structure 518, which is a planar structure made by a metal sheet with substantially the same width W plus two mounting wings on two sides, in an embodiment is configured to be installed by coupling the two mounting wings respectively to the two mounting rails 516A and 516B. Additionally, the mounting rails 516A and 516B are configured to mount a solar panel 514 having a width no smaller than W. The solar panel 514 is directly disposed above the pan structure 518 by a spacing H. For a substantially arbitrary length of the mounting rails, one or more solar panels 514 can be installed one by one along the rails. In a specific embodiment, a plenum structure is then provided by a volume of spatial region confined between a bottom face 512 of the one or more solar panels 514 and a top face 517 of the pan structure 518 and sided by two mounting rails 516A and 516B. The volume of spatial region is defined by the total length covered by the solar panel, the width W, and the spacing H. In the embodiment, the pan structure 518 separates the volume of spatial region from the roof structure 520 at least by a thin layer of air. In certain embodiments, the pan structure 518 does not have to be in parallel to the roof top surface.

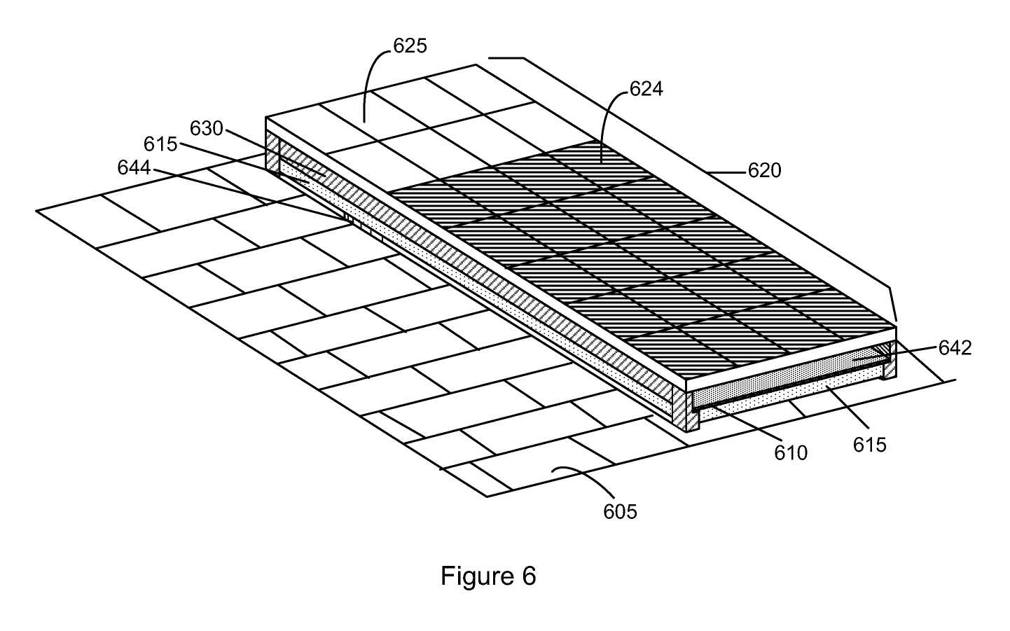

FIG. 6 is a simplified perspective view diagram of a plenum structure associated with a solar panel on a roof of a building structure according to another embodiment of the present invention. This diagram is merely an example, which should not unduly limit the scope of the claims herein. One of ordinary skill in the art would recognize other variations, modifications, and alternatives. In a specific embodiment, a plenum structure is associated with a configuration of a solar panel installed on a roof of a building to provide cooling for both the solar panel and the roof As shown, a solar panel 620 is installed via a pair of mounting rail structures 630 on the roof 605. Each of the two mounting rail structures 630 is separated by a width span and respectively configured to incline with a slope along its length on the roof 605. Depending on a roof structure and orientation, leveled or sloped, the slope of the mounting rail structure 630 can be adjusted so that the solar panel 620 is inclined substantially with a slope that is best for absorbing sun light. In another specific embodiment, the solar panel 620 can be a combination of one or more photovoltaic modules 624 and one or more thermal solar module 625. For example, a solar panel with combined thermal modules 625 and photovoltaic modules 624 has a width no smaller than the width span of the two mounting rail structures 630 and a length covering a portion of the length of the mounting rail structure. One or more solar panels can be added side by side with the solar panel 630 along both the width and the length direction depending on applications.

Further as shown in FIG. 6, a pan structure 610 is inserted between the two mounting rail structures 630. In an embodiment, the pan structure 610 is a metal sheet disposed at a vertical spacing directly under the solar panel 620. The pan structure 610 can be disposed at another vertical spacing above the roof 605 and is shown to be substantially in parallel with the solar panel surface and the roof although the pan structure may not have to have a same incline slope as the roof Additionally, a thickness of thermal insulation material 615, for example, an insulation foam, can be attached beneath the metal sheet between the pan structure 610 and the roof surface 605 underneath. The thermal insulation material 615 still has a clearance gap off the roof surface 605. The clearance gap naturally fills with air as an good insulation material and also provides with a natural air convection effect through the gap. Nevertheless, a spatial volume between an under surface (not visible) of the solar panel 620 and an upper surface (partially visible) of the pan structure 610 sided by the two mounting rail structures 630 forms a plenum structure associated with an installation configuration of the solar panel 620 and the pan structure 610 as illustrated in FIG. 6. The spatial volume has a lower end face 642 and a higher end face (not visible). The lower or higher simply refers to the example as shown in FIG. 6 an embodiment system installation configuration has an incline angle relative to a horizontal plane. In a specific embodiment, the lower end face 642 can be a featureless or specifically configured opening and the higher end can be sealed. In another specific embodiment, the lower end face 642 serves as an intake region for the plenum structure to take an airflow from ambient into the volume of spatial region. The airflow in the plenum structure can be extracted out from an exit region located at the upper portion of the inclined configuration. For example, the exit region may include one or more openings built within an upper portion of the pan structure or a portion of the higher end of the inclined configuration. The airflow through the plenum structure at least partially takes heat energy generated by the solar panel in operation. Because heated air tends to flow upward, the exit region is placed at a relative higher location than the intake region for facilitating the cooling effect of the airflow. The airflow can be additionally controlled by using a power blower to increase flow rate for more efficient heat transfer. In an implementation as shown in FIG. 6, a duct 644 is used to couple with the exit region to guide the airflow into a spatial region below the roof 605. For example, a flow processing system including a blower can be installed in attic or somewhere inside the building for handling the airflow with a controllable flow rate. Of course, there can be many alternatives, variations, and modifications.

In another embodiment, the present invention also provides a method utilizing a plenum structure with an added pan structure for providing a cool roof and making a more efficient solar panel. The plenum structure with added pan structure in the inclined configuration as described above allows an airflow to flow upward naturally for carrying partial heat away from the solar panel in operation, no matter whether the roof is a leveled one or sloped one. Another advantage of the plenum structure with added pan structure is able to provide certain favorable air modulation from both the under surface of the solar panel and the upper surface of the pan structure by using textured surface attachment or adding turbulators.

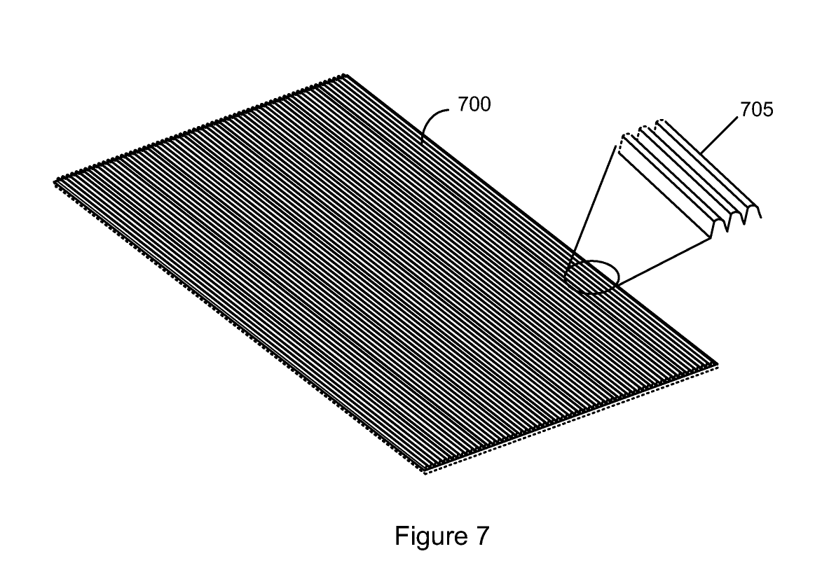

FIG. 7 is an exemplary textured tedlar attachment of a bottom face of a solar panel according to an embodiment of the present invention. This diagram is merely an example, which should not unduly limit the scope of the claims herein. One of ordinary skill in the art would recognize other variations, modifications, and alternatives. As shown, a perspective view of a tedlar surface 700 with textured features 705 is provided. As one of solar panel packaging processes, the tedlar surface 700 can be attached to a bottom face of a solar panel. As an example, shown in the enlarged portion of FIG. 7, the textured features 705 are stripe channels along the length of the solar panel. In an example, the texture stripe channel can have a feature height or width in a dimension of less than 1 millimeter to a few millimeters. Of course, there can be many variations, alternatives, and modifications depending on embodiments. For example, the textured feature can be substantially randomized or ordered in various different orientations. In a specific embodiment, the tedlar attachment has a plurality of random textures with a RMS roughness less than a millimeter.

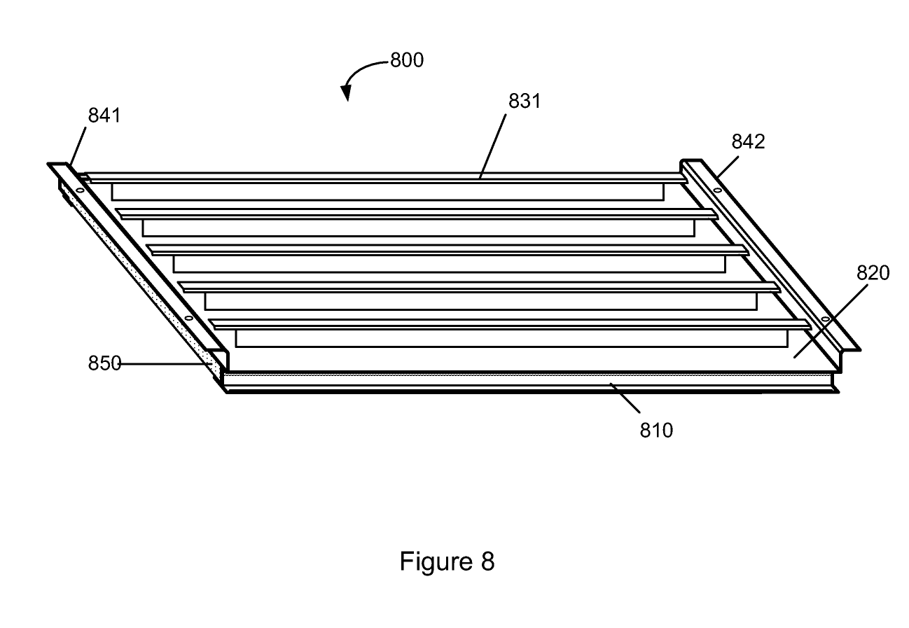

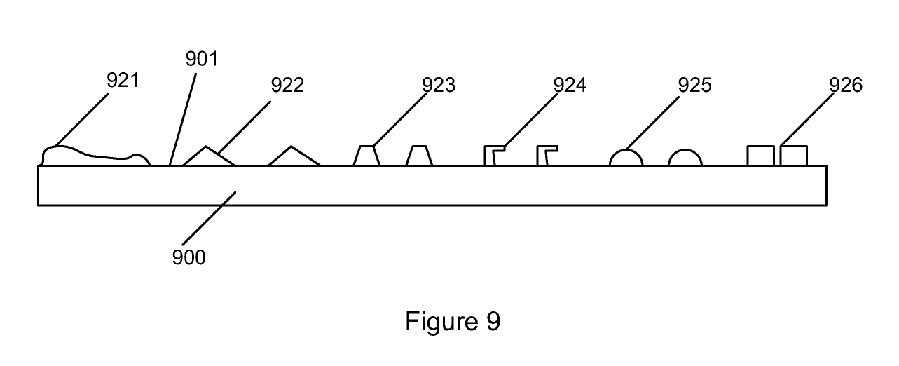

FIG. 8 is an exemplary pan structure with turbulators according to an embodiment of the present invention. This diagram is merely an example, which should not unduly limit the scope of the claims herein. One of ordinary skill in the art would recognize other variations, modifications, and alternatives. As shown, a pan structure 800 includes at least a metal sheet 820 attached with a plurality of turbulators 831. The turbulator 831 has a certain feature height, width, length, and can be in various shapes, depending on embodiments. As shown in this example, the turbulator 831 is a folded fin attached directly on top surface of the metal sheet 820. Many alternative geometric shapes are possible. FIG. 9 shows exemplary textures or turbulators associated with tedlar attachment or pan structure 920 of a plenum structure according to one or more embodiments of the present invention. As shown, a random texture 921, shaped prisms 922 and 923, shaped fins 924, semi-cylinder or hemisphere dome 925, and many others like a combination of shaped combs 926 can be used to form the turbulators for various applications. The feature height of the turbulator 831 can be up to the allowed spacing H between the pan structure 800 and an under surface of a solar panel that together they define a plenum structure as described in FIG. 5. In an implementation, the feature height of the turbulator ranges from about a few centimeters to a few tens of centimeters. The feature width or length (depending on specific turbulator orientation on the metal sheet) can be ranged from about a few millimeters to a few centimeters in width and a feature length ranging from a few centimeters up to the scale of the pan structure 800. Two wing structures 841 and 842 are coupled at two sides of the metal sheet 820 and configured to attach the pan structure 800 respectively to two mounting rail structures (as shown in FIG. 5 and FIG. 6). On other two sides of the metal sheet 820, a mating structure 810 is added for coupling one pan structure to another along that side (although the opposite mating structure is not visible in this perspective view). The pan structure 800 further is configured to allow an insulator material 850 being inserted beneath the metal sheet 820. For example, a piece of insulation foam 850 can be inserted. At least a thin air gap may still exist between the insulator material 850 and a roof top surface under the pan structure. Therefore, the insulator material 850 (plus the air gap) serves as an excellent radiation shield for substantially reducing the thermal radiation transfer towards the roof under the pan structure.

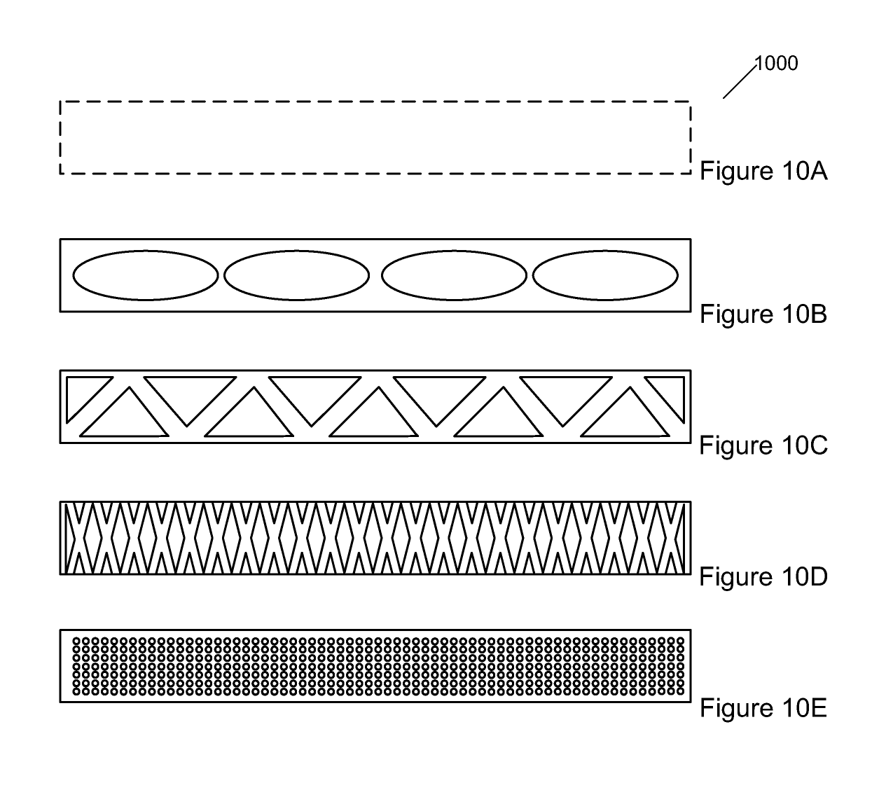

Referring to FIG. 6, as the pan structure and the solar panel are installed via two mounting rail structures on the roof, a plenum structure is formed as a volume of spatial region confined between the under surface (or a textured tedlar attachment) of the solar panel and the upper surface (including added turbulators) of the pan structure and sided at least by the two mounting rail structures with an inclined slope. Furthermore, the lower end of the plenum structure in the sloped direction is utilized as an intake region for drawing an airflow into the volume of spatial region. As shown in FIG. 6, the air intake region 642 is featureless. In one or more embodiments, the air intake region can have certain geometric structures. FIGS. 10A shows a featureless air intake region. FIG. 10B shows an air intake region made of a sheet material with one or more shaped through-holes. In an implementation, the sheet material is attached to the lower end of the plenum structure. In another implementation, the sheet material is part of a frame of a packaged solar panel or part of the pan structure added during installation. FIG. 10C shows an air intake region made of a sheet material with a plurality of triangular shaped through-holes. FIG. 10D shows another example with triangular shaped holes, which can be easily made from folding a shaped flat sheet material with triangular edge-cut and fixing two loose ones together. FIG. 10E shows yet another example of an air intake region made of a sheet material with a plurality of holes each having a diameter of about a few millimeters. This dimension selected for these holes provides an advantage for allowing a free pass-through of hot air during day time operation while allowing a formation of a water film covering each hole from moisture condensation during the night. The water films as formed would block further moisture to enter the plenum structure which might cause harm to the solar panel.

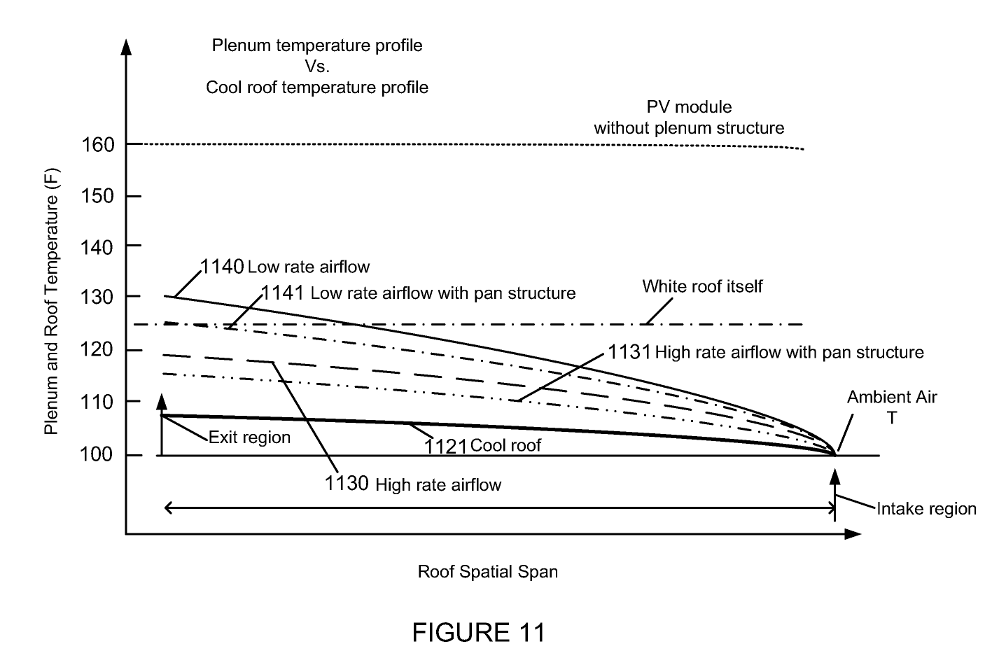

FIG. 11 shows exemplary temperature profiles associated with a plenum structure and cool roof respectively with high/low flow rate and with/without a pan structure according to an embodiment of the present invention. This diagram is merely an example, which should not unduly limit the scope of the claims herein. One of ordinary skill in the art would recognize other variations, modifications, and alternatives. As shown in an example, a curve 1141/1140 respectively represents a plenum structure temperature profile associated with an airflow with a relative low flow rate drawn from an air intake region to an exit region along a length of the plenum structure with/without a pan structure. Assuming ambient air temperature is about 100 Degrees Fahrenheit and a flow rate selected from relative lower side of a range from zero to about 200 sccm, the solar panel in operation transfers heat to the airflow and causes a temperature rise from a substantially ambient temperature at the intake region to about 130 Degrees Fahrenheit at the exit region. The airflow is controlled in terms of the flow rate by an external blower associated with a flow processing system connected via a duct to the exit region. If a pan structure with certain turbulators is added to the plenum structure, the turbulators causes air turbulation around to modify the airflow through the plenum structure effectively enhancing heat transfer. Without driving the blower to increase the flow rate overall, the temperature at the exit region becomes lower and overall along the spatial span of the plenum structure as indicated by curve 1141. To certain degrees, the turbulator on the pan structure (plus a textured tedlar attachment to the bottom face of the solar panel) can achieve results of blowing airflow with higher rate.

With a similar system setup, a curve 1131/1130 respectively represents another plenum structure temperature profile associated with an airflow with a relative high flow rate drawn from the air intake region to the exit region along the length of the plenum structure with/without a pan structure. By driving the external blower, the flow rate of the airflow can be reached to relative higher side of the range from zero to about 200 sccm. Comparing to low rate airflow case, the temperature profile 1131/1130 has an overall lower temperature value due to higher efficiency in heat transfer. Again, adding pan structure to the plenum structure further enhances the heat transfer efficiency. In other words, using turbulators to modulate the airflow or cause some air turbulations in the plenum structure may effectively reduce demand for driving external blower hard if a desirable temperature profile has been obtained at a relative lower flow rate using a plenum structure including pan structure having the turbulators. Furthermore, a curve 1121 is plotted to represent a temperature profile of the cooled roof of the same spatial span covered by the plenum structure with added pan structure. Additionally, an insulator foam can be inserted underneath the pan structure to substantially reduce thermal radiation heat transfer towards the roof A small air gap between the pan structure and the roof also provides a natural convection effect for cooling the roof As the results of all above (plenum structure, pan structure, airflow with certain flow rates, and insulation foam), the roof temperature profile 1121 as shown is a minor sloped curve of temperature slightly increasing from the ambient air temperature to a relative higher value throughout the spatial span covered by the plenum structure. The cool roof temperature curve 1211 is substantially lowered from a (bare) white roof. Therefore, the method and structure according to the present invention provide at least partially a cool roof having a substantially ambient temperature profile throughout the spatial span covered by the plenum structure associated with the solar panel. Of course, there can be other variations, modifications, and alternatives. For example, the flow rate of the volume of air in the plenum structure being transferred for maintaining the roof temperature profiles can be greater than 200 sccm. Depending on the application, an optimum flow rate can always be selected for a specific plenum structure installment with a specific pan structure or textured tedlar attachment, aiming for achieving greatest possible heat reduction of the solar panel and providing a cool roof with a lowest usage in power for driving the airflow. The operation of the solar panel together with the plenum structure can be performed in a well-controlled manner, providing highest possible overall energy conversion efficiency of more than 30%.

Although the above has been described in terms of a cool roof method and system, other alternatives, variations, and modifications can exist. As an example, the method and system can be used to provide thermal energy to a roof, thereby heating it, as well as cooling the roof in some embodiments. In one or more embodiments, the present method and system emits infrared radiation, and possibly other forms of radiation.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A plenum structure for cooling both a roof and a solar module on the roof, the plenum structure comprising:
an upper surface comprising at least a portion of a bottom face of a solar module having a length and a width;
an under surface comprising a top face of a pan structure disposed a first vertical spacing directly below the upper surface and a second vertical spacing above the roof;
a first side face and a second side face respectively coupled to the upper surface and the under surface;
a first end face and a second end face respectively coupled to upper surface, the under surface, the first side face, and the second side face to enclose a spatial volume defined by the length, the width, and the first vertical spacing;
at least one opening structure associated with the first end face for drawing an airflow into the spatial volume; and
an exit opening being disposed in a vicinity of the under surface and the second end face for extracting out the airflow flowing through the spatial volume, wherein the under surface and the under surface modulate the airflow for removing thermal energy generated by the solar module at least partially.

2. The plenum structure of claim 1 wherein the solar module comprises a combination of one or more photovoltaic modules and one or more thermal solar modules.

3. The plenum structure of claim 1 wherein the bottom face of the solar module comprises a tedlar attachment with/without a frame surrounded.

4. The plenum structure of claim 3 wherein the tedlar attachment comprises a plurality of fins with a feature size ranging from a tenth of millimeters to a few millimeters.

5. The plenum structure of claim 3 wherein the tedlar attachment comprises a plurality of random textures with a RMS roughness less than a millimeter.

6. The plenum structure of claim 1 wherein the first side face and the second side face are respectively associated with a first mounting rail and the second mounting rail configured to couple with the solar module and the pan structure to cause both the upper surface and the under surface being inclined substantially with a slope on the roof

7. The plenum structure of claim 1 wherein the first end face comprises a solid sheet material with a plurality of through-holes.

8. The plenum structure of claim 7 wherein the plurality of through-holes comprises a size ranging from a few millimeters up to the width.

9. The plenum structure of claim 1 wherein the exit opening is coupled via a duct to a processing module for controlling the airflow in terms of both the flow rate and a flow direction.

10. The plenum structure of claim 1 wherein the pan structure comprises a solid sheet material including a plurality of shaped turbulators having feature heights up to the first vertical spacing between the upper surface and the under surface for modulating the airflow to enhance heat transfer from the bottom face of the solar module.

11. The plenum structure of claim 10 wherein each of the plurality of shaped turbulators comprises one or a combination of several texture structures selected from an angled fin, a shaped prism, a semi-cylinder, a hemi-sphere dome, a honeycomb, a zigzag comb, and a machined random texture.

12. The plenum structure of claim 10 wherein each of the plurality of shaped turbulators comprises a feature width of about a few millimeters to a few centimeters and a feature length ranging from a few centimeters up to the width.

13. The plenum structure of claim 1 wherein the pan structure further comprises a thermally insulation material installed within the second vertical spacing between the under surface and the roof

14. The plenum structure of claim 1 wherein the airflow determines a first temperature profile through the spatial volume from the one or more openings to the exit opening and the pan structure determines a second temperature profile of the roof underneath.

15. The plenum structure of claim 14 wherein the first temperature profile is at least characterized by substantially reduced temperature values through its bottom face compared to those without the airflow and the second temperature profile is at least characterized by substantially reduced temperature values across the roof compared to a bare roof

16. A method for providing a cool roof utilizing a plenum structure associated with a solar panel mounted on the roof, the method comprising:
mounting a first rail structure and a second rail structure to a roof, the first rail and the second rail being inclined with a slope with respect to a horizontal plane;
installing a pan structure to the first rail structure and the second rail structure, the pan structure comprising a planar material substantially inclined with the slope to cover a portion of the roof, the pan structure having a width and a length;
coupling a solar panel to the first rail structure and the second rail structure, the solar panel being disposed at a distance directly above the pan structure to form a plenum structure characterized by a volume of spatial region caped between the solar panel and the pan structure and sided with the first rain structure and the second rail structure, the plenum structure including at least an intake region near a lower end of the pan structure inclined with the slope and an exit region located substantially near a higher end of the pan structure;
drawing an airflow at a flow rate through the plenum structure from the intake region to the exit region; and
maintaining a temperature profile through the plenum structure using at least the flow rate of the airflow modulated by the pan structure.

17. The method of claim 16 wherein the temperature profile comprises a first temperature value at the intake region, a second temperature value in the vicinity of the exit region, and a third temperature value representing an average temperature outside the plenum structure between the pan structure and the roof, the first temperature value being substantially equal to an ambient air temperature under the sun light, the second temperature value being higher than the first temperature value, and the third temperature being substantially equal to or lower than the ambient air temperature.

18. The method of claim 16 wherein the solar panel comprises a bottom surface inclined with a slope substantially equal to and greater than the slope, the bottom surface being an upper face of the plenum structure.

19. The method of claim 18 wherein the bottom surface comprises a tedlar attachment having a plurality of machine roughened textures with a RMS roughness less than a millimeter.

20. The method of claim 16 wherein the solar panel comprises a combination of one or more photovoltaic modules and one or more thermal solar modules.

21. The method of claim 16 wherein the pan structure comprises a plurality of turbulators protruded above the planar material, each of the plurality of turbulators having a feature height up to the distance between the bottom face and the planar material.

22. The method of claim 21 wherein each of the plurality of turbulators comprises one or a combination of several texture structures selected from an angled fin, a shaped prism, a semi-cylinder, a hemi-sphere dome, a honeycomb, a zigzag comb, and a machined random texture for causing local air turbulation and flow rate modulation for enhancing thermal energy transfer from the solar module to the airflow.

23. The method of claim 21 wherein each of the plurality of turbulators comprises a feature width of about a few millimeters to a few centimeters and a feature length ranging from a few centimeters up to the width or length of the pan structure.

24. The method of claim 16 wherein the pan structure further comprises a thermal insulation material installed such that an air gap exists between the thermal insulation material and the roof.

25. The method of claim 16 wherein the roof has a slope ranging from zero to substantially greater than 1.0.

26. The method of claim 16 wherein drawing the airflow at the flow rate through the plenum structure from the intake region to the exit region comprises using a flow processing module coupled to the exit region.
